(19) United States
(12) Patent Application Publication
(10) Pub. No.: US 2011/0221527 A1
(43) Pub. Date: Sep. 15, 2011

(54) DIGITAL PREDISTORTION APPARATUS AND METHOD FOR IMPROVING PERFORMANCE USING PEAK LEVEL EXPANSION

(75) Inventors: Young-Yoon Woo, Hwaseong-si (KR); Sung-Chul Hong, Yongin-si (KR)

(73) Assignee: SAMSUNG ELECTRONICS CO., LTD., Suwon-si (KR)

(21) Appl. No.: 13/048,688

(22) Filed: Mar. 15, 2011

(30) Foreign Application Priority Data
Mar. 15, 2010 (KR) 10-2010-0022787

(51) Int. Cl. H03F 1/26

(52) U.S. Cl. 330/149

(57) ABSTRACT

A method an apparatus improve linearization performance and reduce a convergence time of a Digital Pre-Distorter of a power amplifier. An input signal is received. A peak level of the input signal is expanded based on an expansion threshold. And the expanded peak level of the input signal is linearized through Digital Pre-Distorter (DPD) training on the expanded input signal.

### CROSS-REFERENCE TO RELATED APPLICATION(S) AND CLAIM OF PRIORITY

The present application claims the benefit under 35 U.S.C. §119(a) to a Korean patent application filed in the Korean Intellectual Property Office on Mar. 15, 2010, and assigned Serial No. 10-2010-0022787, the entire disclosure of which is hereby incorporated by reference.

### TECHNICAL FIELD OF THE INVENTION

The present invention relates generally to an apparatus and a method for improving performance of a Digital Pre-Distorter (DPD) of a power amplifier. More particularly, the present invention relates to an apparatus and a method for improving linearization performance and reducing a convergence time by expanding a peak level over a certain level of an input signal to linearize and using as a training signal of a DPD.

### BACKGROUND OF THE INVENTION

A digital linearizer linearly amplifies an input modulation signal by comparing the input signal with an output signal and minimizing distortion of the output signal using a Digital Pre-Distorter (DPD), so as to linearize a power amplifier.

To perform a correction algorithm for extracting the distortion and performing the DPD, the input signal representing the entire signal and the corresponding output signal are necessary.

When the modulation signal to linearize is used as a training signal, real-time linearization and transmission of the modulation signal can be carried out concurrently. However, it is difficult to accurately extract a predistortion signal due to a peak level limit of the modulation signal.

DPD input and output values can be obtained by using an inverse function of the input and output values of the power amplifier. The DPD input and output signals can be acquired from maximum input and output signals of the amplifier. Based on this, the linearized output signal can be produced. However, to obtain the linearized value, it is required to obtain the DPD signal through extrapolation of the DPD signal acquired from the inverse function of the amplifier.

The derived DPD signal, which cannot accurately reflect characteristics of the power amplifier, degrades the linearization performance and increases the linearization time and the number of repetitions.

A conventional DPD system uses the input signal as the training signal for the DPD training, and thus requires the extrapolation when the peak level is over a certain level. The DPD output signal yielded through the extrapolation, which cannot accurately reflect the characteristics of the power amplifier, degrades the linearization performance and increases the linearization time and the number of the repetitions.

### SUMMARY OF THE INVENTION

To address the above-discussed deficiencies of the prior art, it is a primary aspect of the present invention to provide Digital Pre-Distorter (DPD) apparatus and method for improving performance using peak level expansion.

Another aspect of the present invention is to provide an apparatus and a method for improving linearization performance and reducing a convergence time of a Digital Pre-Distorter (DPD) system.

According to one aspect of the present invention, a digital predistortion method includes receiving an input signal. A peak level of the input signal is expanded. And the expanded peak level of the input signal is linearized through Digital Pre-Distorter (DPD) training on the expanded input signal.

According to another aspect of the present invention, a digital predistortion apparatus includes a peak expander for receiving an input signal and expanding a peak level of the input signal. A Digital Pre-Distorter (DPD) linearizes the expanded peak level of the input signal through DPD training on the expanded input signal.

According to yet another aspect of the present invention, an apparatus for performing linearization is provided. A controller receives and input signal, expands a peak level of the input signal based on an expansion threshold, and linearizes the expanded peak level of the input signal through Digital Pre-Distorter (DPD) training on the expanded input signal.

Other aspects, advantages, and salient features of the invention will become apparent to those skilled in the art from the following detailed description, which, taken in conjunction with the annexed drawings, discloses embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a Digital Pre-Distorter (DPD) apparatus according to an embodiment of the present invention;

FIG. 2 illustrates a graph of a Complementary Cumulative Distribution Function (CCDF) for a signal range of a particular modulation signal, expansion threshold Vth determination, and peak level expansion in a time waveform according to an embodiment of the present invention;

FIG. 3 illustrates a structure and input/output waveforms of a peak expander of a DPD system according to an embodiment of the present invention;

FIG. 4 illustrates PA and DPD in the peak level expansion and magnitude of input/output signal characteristics of the system according to an embodiment of the present invention; and

FIG. 5 illustrates a digital predistortion process according to an embodiment of the present invention.

Throughout the drawings, like reference numerals will be understood to refer to like parts, components and structures.

### DETAILED DESCRIPTION OF THE INVENTION

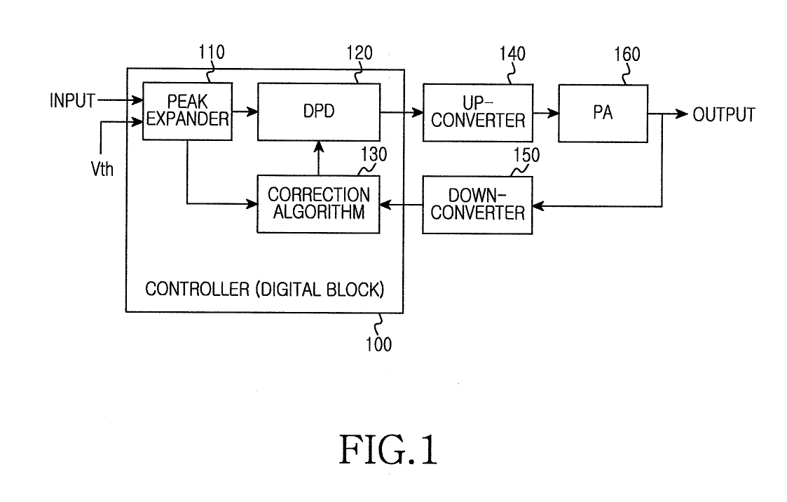

FIGS. 1 through 5, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged system.

Embodiments of the present invention provide Digital Pre-Distorter (DPD) apparatus and method for improving performance using peak level expansion.

FIG. 1 illustrates a DPD apparatus according to an embodiment of the present invention.

The DPD apparatus of FIG. 1 uses an actual modulation signal as a training signal for DPD training and expands a peak value over a certain level (Vth: expansion threshold) of the signal to an intended level. The intended level may be determined by the experiment, measurement or calculation by operator or designer.

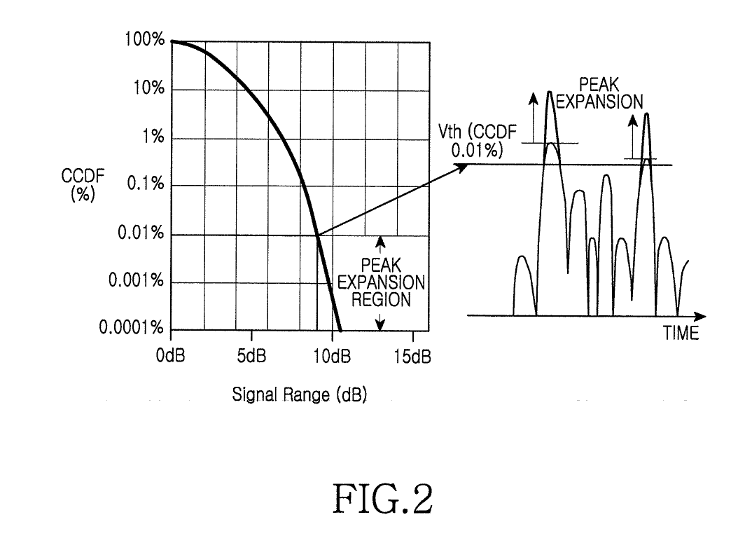

The DPD apparatus determines an inverse function by capturing input and output characteristics of a power amplifier, and thus implements a DPD block. At this time, the expansion threshold Vth is shown in FIG. 2.

The DPD apparatus includes a controller 100 which is a digital block, an up-converter 140, a down-converter 150, and a Power Amplifier (PA) 160. The controller 100 includes a peak expander 110, a DPD 120, and a correction algorithm 130.

The up-converter 140 up-converts an output signal of the DPD 120 and outputs the up-converted signal to the PA 160. The PA 160 amplifies the up-converted signal. The down-converter 150 down-converts the signal amplified by the PA 160 and outputs the down-converted signal to the correction algorithm 130.

The correction algorithm 130 extracts distortion by comparing the down-converted signal and an output signal of the peak expander 110, and outputs the extracted distortion to the DPD 120.

The peak expander 110 extracts a value over the expansion threshold from the input signal, expands the value over the expansion threshold to the intended level, adds the expanded value to the original modulation signal, and thus outputs the signal with the peak level expanded. Hence, when the input signal with the peak level expanded is used as the training signal of the DPD 120, it is possible to implement solely with the inverse function of the input and output values of the PA without extrapolation.

The DPD 120 applies DPD to the signal output from the peak expander 110 by using the distortion provided from the correction algorithm 130. The algorithm may usually vary depending on the implementation, a manufacturer, and a provider.

As constructed above, the controller 100 may perform the functions of the peak expander 110, the DPD 120, and the correction algorithm 130. Herein, they are separately provided to distinguish their functions.

Accordingly, in an embodiment, the controller 100 may process all or a subset of the functions of the peak expander 110, the DPD 120, and the correction algorithm 130.

FIG. 2 illustrates a graph of a Complementary Cumulative Distribution Function (CCDF) for a signal range of a particular input modulation signal, expansion threshold Vth determination, and peak level expansion in a time waveform according to an embodiment of the present invention. The input modulation signal may be referred to a input signal.

The determination, by a peak expander, of a Peak to Average Power Ratio (PAPR) of the input modulation signal may define the signal range that corresponds to the CCDF value up to 0.01%. In the modulation signal of FIG. 2, the PAPR is approximately 9 dB.

The signal of the peak level over 9 dB, which has a quite low frequency, scarcely affects characteristics (Error Vector Magnitude (EVM), code domain error) of the modulation signal.

The present invention defines a point of the CCDF value 0.01% as the expansion threshold Vth and expands the peak value over the expansion threshold to the intended level. The expanded signal, which has quite a low signal frequency, hardly affects the entire signal characteristics. Because the expanded signal is restored to the intended signal after the DPD linearization, it does not affect the signal quality.

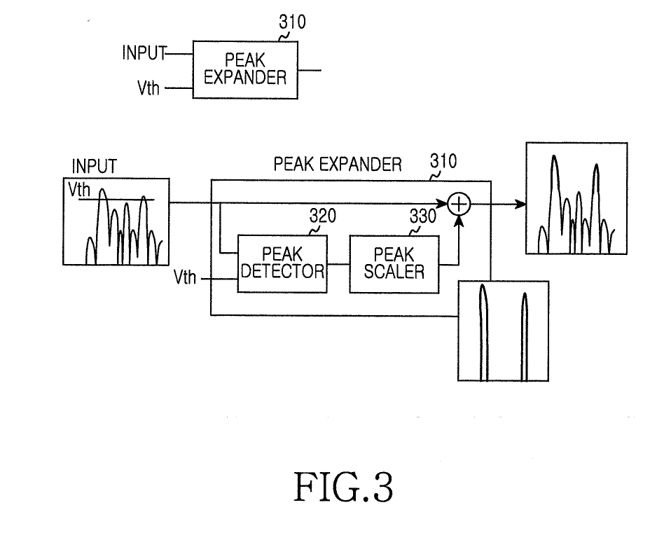

FIG. 3 illustrates a structure and input/output waveforms of the peak expander of a DPD system according to an embodiment of the present invention.

In the peak expander 310, when a peak detector 320 extracts the value(s) over the expansion threshold based on CCDF and a peak scaler 330 expands the value(s) over the expansion threshold to the intended level and adds the expanded value(s) to the original modulation signal, the signal with the expanded peak level can be generated. The peak expander 310 is substantially the same as the peak expander 110 of FIG. 1.

As such, when the input signal with the expanded peak level is used as the training signal of the DPD, the DPD 120 of FIG. 1 may be implemented merely with the inverse function with the input and output values of the power amplifier without extrapolation.

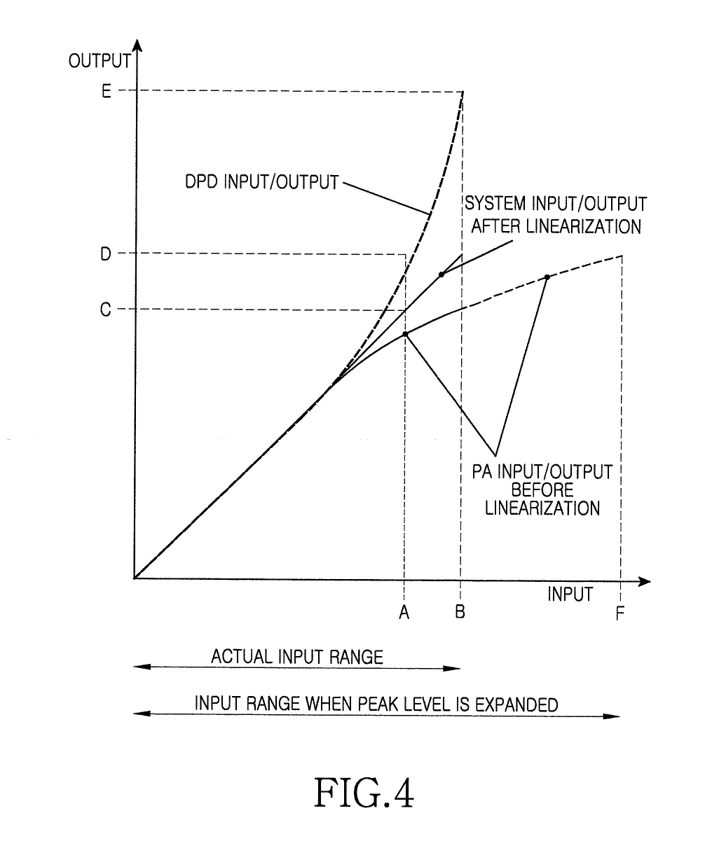

FIG. 4 illustrates the PA and the DPD in the peak level expansion, and magnitude of input/output signal characteristics of the system according to an embodiment of the present invention.

While the actual input signal may linearize until the point (a, c) according to the point (b, c), the peak level expansion signal may additionally linearize until the point (b, d) according to the point (f, d). Thus, the linearization may be achieved up to the intended level without extrapolation. Consequently, the linearization performance may be improved and the convergence time may be reduced in the DPD system.

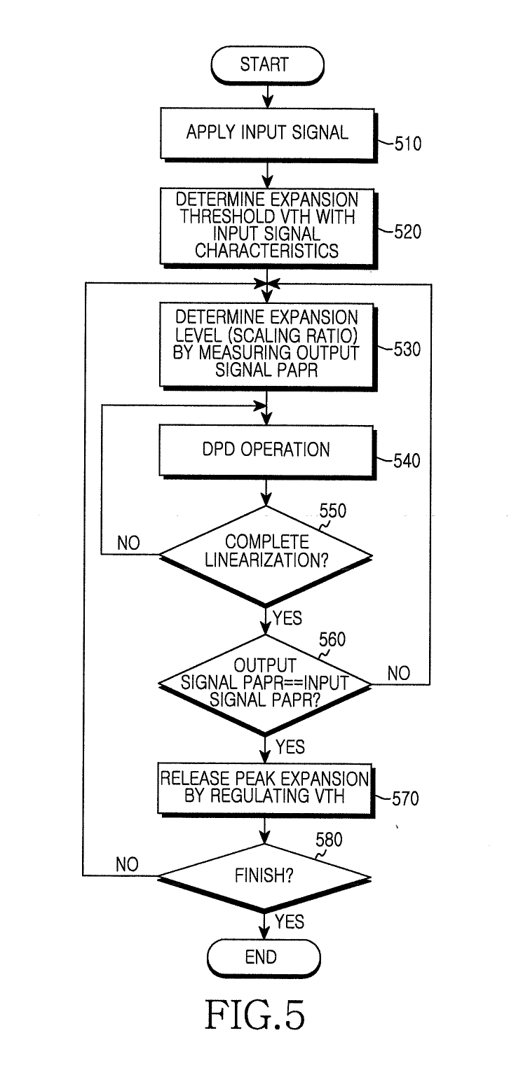

FIG. 5 illustrates a digital predistortion process according to an embodiment of the present invention.

When the input signal is applied in block 510, the peak expander determines the expansion threshold Vth using the CCDF characteristics of the input signal in block 520 and determines a expansion level by determining the PAPR of the output signal of a PA in block 530. The expansion level may be intended level.

In block 540, the DPD operation (training) is performed for the output signal provided from the peak expander such that the input signal is linearized. During the DPD operation, the distortion is provided to the DPD 120 of FIG. 1 according to the corresponding algorithm.

When the linearization is completed through the DPD training in block 550, the DPD system determines whether the PAPR of the output signal is substantially equal to the PAPR of the input signal; that is, whether the linearization of the peak level is completed in block 560. When the linearization is completed, the method regulates the Vth and releases the peak expansion function in block 570. The input signal may be an input modulation signal and the output signal may be the output signal of a PA.

When the linearization through the DPD training is not finished in block 550, the DPD system repeats the DPD training in block 540.

When the PAPR of the output signal is not substantially equal to the PAPR of the input signal in block 560, the DPD system re-determines the expansion level in block 530 and repeats the DPD training in block 540.

By expanding the peak level of the input signal actually modulated in the transmission system and using the input signal with the peak level expanded as the training signal for the DPD training of the DPD system, more accurate DPD output signal may be obtained.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A digital predistortion method comprising:
receiving, by a peak expander, an input signal;
expanding, by the peak expander, a peak level of the input signal; and
linearizing, by a Digital Pre-Distorter (DPD), the expanded peak level of the input signal through DPD training on the expanded input signal.

2. The digital predistortion method of claim 1, further comprising:
up-converting, by an up-converter, and amplifying, by an amplifier, the peak level linearized signal;
down-converting, by a down-converter, the amplified signal; and
providing, by the down-converter, the down-converted signal as an input for the DPD training.

3. The digital predistortion method of claim 1, wherein expanding the peak level of the input signal comprises:
determining an expansion threshold and an expansion level of the peak level; and
expanding a portion of the input signal that is over the expansion threshold according to the expansion level.

4. The digital predistortion method of claim 3, wherein the expansion threshold is determined based on Complementary Cumulative Distribution Function (CCDF) characteristics of the input signal, and the expansion level is determined based on a Peak to Average Power Ratio (PAPR) of an output signal.

5. The digital predistortion method of claim 2, wherein linearizing the expanded peak level of the input signal through the DPD training on the expanded input signal comprises:
extracting a distortion by comparing the down-converted signal of the amplified signal with the input signal; and
applying the DPD training to the expanded input signal by using the distortion.

6. The digital predistortion method of claim 4, further comprising:
determining, by a controller, whether the linearization through the DPD training is completed; and
when the linearization is not completed, repeating, by the controller, the DPD training on the expanded signal.

7. The digital predistortion method of claim 6, further comprising:
determining, by the controller, whether a PAPR of the peak level linearized signal is substantially equal to a PAPR of the input signal,
in response to determining that the PAPR of the peak level linearized signal is not substantially equal to the PAPR of the input signal, re-expanding, by the controller, the peak level of the input signal.

8. A digital predistortion apparatus comprising:
a peak expander configured to receive an input signal and expand a peak level of the input signal; and
a Digital Pre-Distorter (DPD) configured to linearize the expanded peak level of the input signal through DPD training on the expanded input signal.

9. The digital predistortion apparatus of claim 8, further comprising:
an up-converter configured to up-convert the peak level linearized signal;
an amplifier configured to amplify the up-converted signal; and
a down-converter configured to down-convert the amplified signal and provide the down-converted signal to the DPD as an input for the DPD training.

10. The digital predistortion apparatus of claim 8, wherein, the peak expander is further configured to determine an expansion threshold and an expansion level of the peak level and expand a portion of the input signal that is over the expansion threshold according to the expansion level to expand the peak level of the input signal.

11. The digital predistortion apparatus of claim 10, wherein the expansion threshold is determined based on Complementary Cumulative Distribution Function (CCDF) characteristics of the input signal, and the expansion level is determined by determining a Peak to Average Ratio (PAPR) of the output signal.

12. The digital predistortion apparatus of claim 9, wherein, the DPD is further configured to extract a distortion by comparing the down-converted signal of the amplified signal with the input signal, and apply the DPD training to the expanded input signal by using the distortion to linearize the expanded peak level of the input signal.

13. The digital predistortion apparatus of claim 11, further comprising a controller configured to determine whether the linearization through the DPD training is completed, and repeat the DPD training on the expanded signal when the linearization is not completed.

14. The digital predistortion apparatus of claim 13, wherein the controller is further configured to determine whether a PAPR of the peak level linearized signal is substantially equal to a PAPR of the input signal, and re-expand the peak level of the input signal in response to determining that the PAPR of the peak level linearized signal is not substantially equal to the PAPR of the input signal.

15. An apparatus for performing linearization, the apparatus comprising:
a controller configured to receive an input signal, expand a peak level of the input signal based on an expansion threshold, and linearize the expanded peak level of the input signal through Digital Pre-Distorter (DPD) training on the expanded input signal.

16. The apparatus of claim 15, further comprising:
an up-converter configured to up-convert the peak level linearized signal;
an amplifier configured to amplify the up-converted signal; and
a down-converter configured to down-convert the amplified signal and provide the down-converted signal to the controller as an input for the DPD training.

17. The apparatus of claim 15, wherein the controller is further configured to determine the expansion threshold and a scaling ratio, and expand a portion of the input signal that is over the expansion threshold according to the scaling ratio to expand the peak level of the input signal,
wherein the expansion threshold is determined based on Complementary Cumulative Distribution Function (CCDF) characteristics of the input signal, and the expansion level is determined by determining a Peak to Average Ratio (PAPR) of the output signal.

18. The apparatus of claim 15, wherein, the controller is further configured to extract a distortion by comparing the down-converted signal of the amplified signal with the input signal, and apply the DPD training to the expanded input signal by using the distortion to linearize the expanded peak level of the input signal.

19. The apparatus of claim 17, wherein the controller is further configured to determine whether the linearization through the DPD training is completed, and repeat the DPD training on the expanded signal when the linearization is not completed.

20. The apparatus of claim 19, wherein the controller is further configured to determine whether a PAPR of the peak level linearized signal is substantially equal to a PAPR of the input signal, and re-expand the peak level of the input signal in response to determining that the PAPR of the peak level linearized signal is not substantially equal to the PAPR of the input signal.
